(19) United States
(12) Patent Application Publication
(10) Pub. No.: US 2020/0136006 A1
(43) Pub. Date: Apr. 30, 2020

(54) THERMOELECTRIC ELEMENT BASED WATCH

(71) Applicant: Sridhar Kasichainula, Fremont, CA (US)

(72) Inventor: Sridhar Kasichainula, Fremont, CA (US)

(21) Appl. No.: 16/726,251

(22) Filed: Dec. 24, 2019

Related U.S. Application Data
(63) Continuation-in-part of application No. 15/808,902, filed on Nov. 10, 2017.
Application No. 15/808,902 is a continuation-in-part of application No. 14/564,072, filed on Dec. 8, 2014.
Application No. 15/808,902 is a continuation-in-part of application No. 14/711,810, filed on May 14, 2015, now Pat. No. 10,141,492.
Application No. 14/711,810 is a continuation-in-part of application No. 15/368,683, filed on Dec. 5, 2016, now Pat. No. 10,290,794.
(60) Provisional application No. 61/912,561, filed on Dec. 6, 2013.

(51) Int. Cl. H01L 35/32; H01L 35/04; H01L 35/14; G04C 10/00

(52) U.S. Cl. CPC H01L 35/32; G04C 10/00; H01L 35/14; H01L 35/04

(57) ABSTRACT

A thermoelectric element based watch includes a first thermally conductive element configured to serve as a hot end, a thin-film thermoelectric layer of dimensional thickness less than or equal to 100 μm including a number of sets of thermoelectric legs formed on a substrate, and a second thermally conductive element attached to a body case thereof configured to serve as a cold end. The thermoelectric element based watch also includes a number of metallic pins directly contacting both the second thermally conductive element and one or more set(s) of the number of sets of the thermoelectric legs of the thin-film thermoelectric layer. Based on the contact of the number of metallic pins with both the second thermally conductive element and the one or more set(s), the thermoelectric element based watch is configured to be powered in accordance with a temperature difference between the hot end and the cold end thereof.

### CLAIM OF PRIORITY

This application is a Continuation-in-Part application of co-pending U.S. patent application Ser. No. 15/808,902 titled FLEXIBLE THIN-FILM BASED THERMOELECTRIC DEVICE WITH SPUTTER DEPOSITED LAYER OF N-TYPE AND P-TYPE THERMOELECTRIC LEGS filed on Nov. 10, 2017, which is a Continuation-in-Part application of co-pending U.S. patent application Ser. No. 14/564,072 titled VOLTAGE GENERATION ACROSS TEMPERATURE DIFFERENTIALS THROUGH A THERMOELECTRIC LAYER COMPOSITE filed on Dec. 8, 2014, which is a conversion application of U.S. Provisional Application No. 61/912,561 also titled VOLTAGE GENERATION ACROSS TEMPERATURE DIFFERENTIALS THROUGH A THERMOELECTRIC LAYER COMPOSITE filed on Dec. 6, 2013, U.S. patent application Ser. No. 14/711,810 titled ENERGY HARVESTING FOR WEARABLE TECHNOLOGY THROUGH A THIN FLEXIBLE THERMOELECTRIC DEVICE filed on May 14, 2015 and issued as U.S. Pat. No. 10,141,492 on Nov. 27, 2018, and U.S. patent application Ser. No. 15/368,683 titled PIN COUPLING BASED THERMOELECTRIC DEVICE filed on Dec. 5, 2016 and issued as U.S. Pat. No. 10,290,794 on May 14, 2019. The content of the aforementioned applications are incorporated by reference in entirety thereof.

### FIELD OF TECHNOLOGY

This disclosure relates generally to watches and, more particularly, to a thermoelectric element based watch.

### BACKGROUND

A quartz watch may be battery powered. The battery of the quartz watch may frequently need to be replaced, leading to bad user experience of a wearer thereof, in addition to costs associated therewith. Harvesting body heat to thermoelectrically power the quartz watch may involve a large amount of heat energy being absorbed into a case thereof. The accompanying rise in temperature inside the case may result in temperatures at both ends of a thermoelectric element embedded in the watch being in equilibrium with each other. In other words, a temperature difference between both ends of the thermoelectric element becomes zero, resulting in the thermoelectric element being brought to a state capable of generating no power.

### SUMMARY

Disclosed are devices and a component of a thermoelectric element based watch.

In one aspect, a thermoelectric element based watch includes a first thermally conductive element configured to serve as a hot end of the thermoelectric element based watch, and a thin-film thermoelectric layer including a number of sets of thermoelectric legs formed on a substrate. The hot end is configured to directly contact a body part of a user wearing the thermoelectric element based watch, and each set of the number of sets includes an N-type thermoelectric leg and a P-type thermoelectric leg electrically in contact with one another. A dimensional thickness of the thin-film thermoelectric layer is less than or equal to 100 μm, and the substrate of the thin-film thermoelectric layer directly contacts the first thermally conductive element on an inside of the thermoelectric element based watch as compared to an outside of the first thermally conductive element configured to serve as the hot end.

The thermoelectric element based watch also includes a second thermally conductive element attached to a body case of the thermoelectric element based watch configured to serve as a cold end thereof. Further, the thermoelectric element based watch includes a number of metallic pins directly contacting both the second thermally conductive element on another inside of the thermoelectric element based watch as compared to another outside of the second thermally conductive element configured to serve as the cold end and one or more set(s) of the number of sets of the thermoelectric legs of the thin-film thermoelectric layer. Based on the direct contact of the number of metallic pins with both the second thermally conductive element and the one or more set(s) of the number of sets of the thermoelectric legs of the thin-film thermoelectric layer, the thermoelectric element based watch is configured to be powered in accordance with a temperature difference between the hot end and the cold end thereof.

In another aspect, a thermoelectric component of a watch includes a thin-film thermoelectric layer including a number of sets of thermoelectric legs formed on a substrate. Each set of the number of sets includes an N-type thermoelectric leg and a P-type thermoelectric leg electrically in contact with one another. A dimensional thickness of the thin-film thermoelectric layer is less than or equal to 100 μm, and the substrate of the thin-film thermoelectric layer is configured to directly contact a first thermally conductive element of the watch on an inside thereof as compared to an outside of the first thermally conductive element configured to serve as a hot end of the watch. The hot end is configured to directly contact a body part of a user wearing the watch.

The thermoelectric component of the watch also includes a number of metallic pins directly contacting one or more set(s) of the number of sets of the thermoelectric legs of the thin-film thermoelectric layer and configured to also directly contact a second thermally conductive element of the watch on another inside thereof as compared to another outside of the second thermally conductive element configured to serve as a cold end of the watch. Based on the direct contact of the number of metallic pins with both the second thermally conductive element and the one or more set(s) of the number of sets of the thermoelectric legs of the thin-film thermoelectric layer, the watch is configured to be powered in accordance with a temperature difference between the hot end and the cold end thereof.

In yet another aspect, a thermoelectric element based watch includes a first thermally conductive element configured to serve as a hot end of the thermoelectric element based watch, and a thin-film thermoelectric layer including a number of sets of thermoelectric legs formed on a substrate. The hot end is configured to directly contact a body part of a user wearing the thermoelectric element based watch, and each set of the number of sets includes an N-type thermoelectric leg and a P-type thermoelectric leg electrically in contact with one another. A dimensional thickness of the thin-film thermoelectric layer is less than or equal to 100 μm, and the substrate of the thin-film thermoelectric layer directly contacts the first thermally conductive element on an inside of the thermoelectric element based watch as compared to an outside of the first thermally conductive element configured to serve as the hot end.

The thermoelectric element based watch also includes a second thermally conductive element attached to a body case of the thermoelectric element based watch configured to serve as a cold end thereof. Further, the thermoelectric element based watch includes a number of metallic pins directly contacting both the second thermally conductive element on another inside of the thermoelectric element based watch as compared to another outside of the second thermally conductive element configured to serve as the cold end and one or more set(s) of the number of sets of the thermoelectric legs of the thin-film thermoelectric layer. Based on the direct contact of the number of metallic pins with both the second thermally conductive element and the one or more set(s) of the number of sets of the thermoelectric legs of the thin-film thermoelectric layer, the thermoelectric element based watch is configured to be powered in accordance with a temperature difference between the hot end and the cold end thereof.

An area between the second thermally conductive element and the thin-film thermoelectric layer, and around the number of metallic pins, is vacuum insulated or filled with a spacer material.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a thermoelectric device.

FIG. 2 is a schematic view of an example thermoelectric device with alternating P and N elements.

FIG. 3 is a top schematic view of a thermoelectric device component, according to one or more embodiments.

FIG. 4 is a process flow diagram detailing the operations involved in realizing a patterned flexible substrate of a thermoelectric device as per a design pattern, according to one or more embodiments.

FIG. 5 is a schematic view of the patterned flexible substrate of FIG. 4, according to one or more embodiments.

FIG. 6 is a schematic view of the patterned flexible substrate of FIG. 4 with N-type thermoelectric legs, P-type thermoelectric legs, a barrier layer and conductive interconnects, according to one or more embodiments.

FIG. 7 is a process flow diagram detailing the operations involved in sputter deposition of the N-type thermoelectric legs of FIG. 6 on the patterned flexible substrate (or, a seed metal layer) of FIG. 5, according to one or more embodiments.

FIG. 8 is a process flow diagram detailing the operations involved in deposition of the barrier layer of FIG. 6 on top of the sputter deposited pairs of P-type thermoelectric legs and the N-type thermoelectric legs of FIG. 6 and forming the conductive interconnects of FIG. 6 on top of the barrier layer, according to one or more embodiments.

FIG. 9 is a process flow diagram detailing the operations involved in encapsulating the thermoelectric device of FIG. 4 and FIG. 6, according to one or more embodiments.

FIG. 10 is a schematic view of a flexible thermoelectric device embedded within a watch strap of a watch completely wrappable around a wrist of a human being.

FIG. 11 is a schematic view of a flexible thermoelectric device wrapped around a heat pipe.

FIG. 12 is a schematic front view of a thermoelectric element based quartz watch, according to one or more embodiments.

FIG. 13 is a schematic perspective view of the thermoelectric element based quartz watch of FIG. 12, according to one or more embodiments.

Other features of the present embodiments will be apparent from the accompanying drawings and from the detailed description that follows.

### DETAILED DESCRIPTION

Example embodiments, as described below, may be used to provide devices and/or a component of a thermoelectric element based watch. Although the present embodiments have been described with reference to specific example embodiments, it will be evident that various modifications and changes may be made to these embodiments without departing from the broader spirit and scope of the various embodiments.

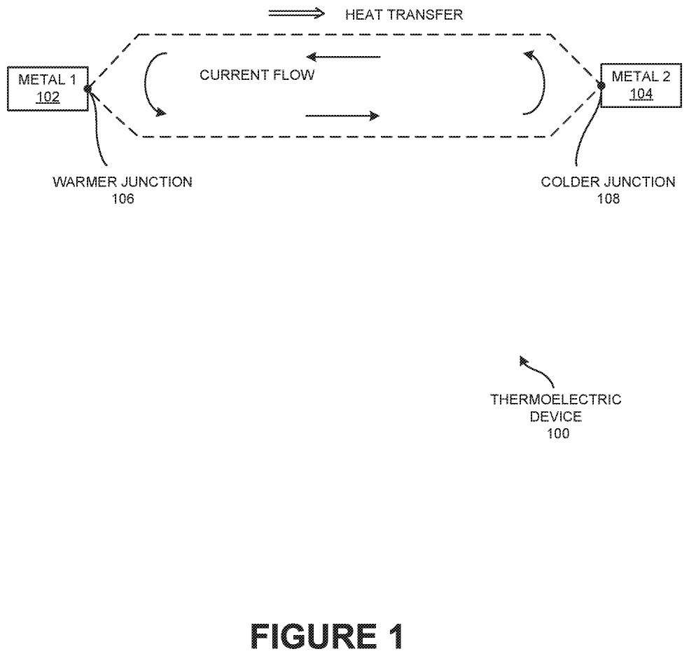

FIG. 1 shows a thermoelectric device 100. Thermoelectric device 100 may include different metals, metal 1 102 and metal 2 104, forming a closed circuit. Here, a temperature difference between junctions of said dissimilar metals leads to energy levels of electrons therein shifted in a dissimilar manner. This results in a potential/voltage difference between the warmer (e.g., warmer junction 106) of the junctions and the colder (e.g., colder junction 108) of the junctions. The aforementioned conversion of heat into electricity at junctions of dissimilar metals is known as Seebeck effect.

The most common thermoelectric devices in the market may utilize alternative P and N type legs/pellets/elements made of semiconducting materials. As heat is applied to one end of a thermoelectric device based on P and N type elements, charge carriers thereof may be released into the conduction band. Electron (charge carrier) flow in the N type element may contribute to a current flowing from the end (hot end) where the heat is applied to the other end (cold end). Hole (charge carrier) flow in the P type element may contribute to a current flowing from the other end (cold end) to the end (hot end) where the heat is applied. Here, heat may be removed from the cold end to prevent equalization of charge carrier distribution in the semiconductor materials due to migration thereof.

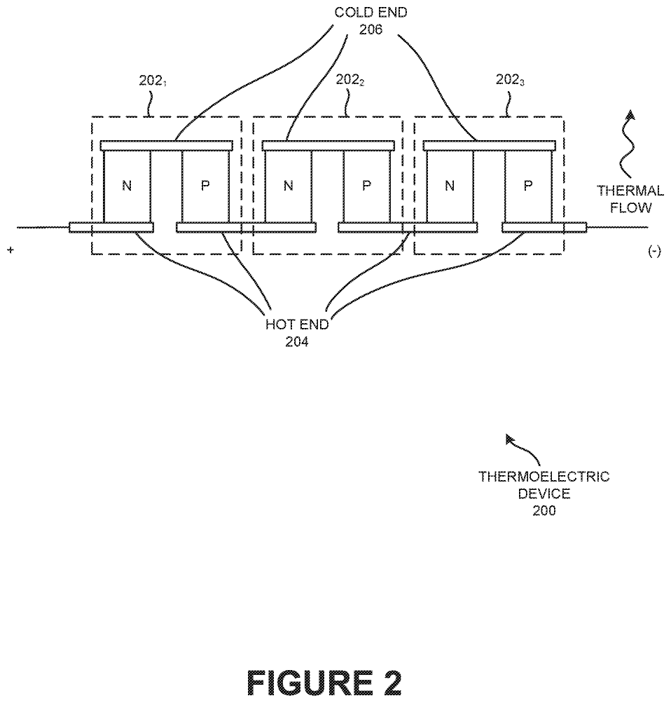

In order to generate voltage at a meaningful level to facilitate one or more application(s), typical thermoelectric devices may utilize alternating P and N type elements (legs/pellets) electrically coupled in series (and thermally coupled in parallel) with one another, as shown in FIG. 2. FIG. 2 shows an example thermoelectric device 200 including three alternating P and N type elements 202₁₋₃. The hot end (e.g., hot end 204) where heat is applied and the cold end (e.g., cold end 206) are also shown in FIG. 2.

Typical thermoelectric devices (e.g., thermoelectric device 200) may be limited in application thereof because of rigidity, bulkiness and high costs (>$20/watt) associated therewith. Also, these devices may operate at high temperatures using active cooling. Exemplary embodiments discussed herein provide for a thermoelectric platform (e.g., enabled via roll-to-roll sputtering on a flexible substrate (e.g., plastic)) that offers a large scale, commercially viable, high performance, easy integration and inexpensive (<20 cents/watt) route to flexible thermoelectrics.

In accordance with the exemplary embodiments, P and N thermoelectric legs may be deposited on a flexible substrate (e.g., plastic) using a roll-to-roll process that offers scalability and cost savings associated with the N and P materials. In a typical solution, bulk legs may have a height in millimeters (mm) and an area in mm². In contrast, N and P bulk legs described in the exemplary embodiments discussed herein may have a height in microns (μm) and an area in the μm² to mm² range.

Examples of flexible substrates may include but are not limited to aluminum (Al) foil, a sheet of paper, teflon, plastic, polyimide and a single/double-sided metal (e.g., copper (Cu)) clad laminate. As will be discussed below, exemplary embodiments involve processes for manufacturing/fabrication of thermoelectric devices/modules that enable flexibility thereof not only in terms of substrates but also in terms of thin films/thermoelectric legs/interconnects/packaging. Preferably, exemplary embodiments provide for thermoelectric devices/modules completely wrappable and bendable around other devices utilized in specific applications, as will be discussed below. Further, exemplary embodiments provide for manufactured/fabricated thermoelectric devices/modules that are each less than or equal to 100 μm in dimensional thickness.

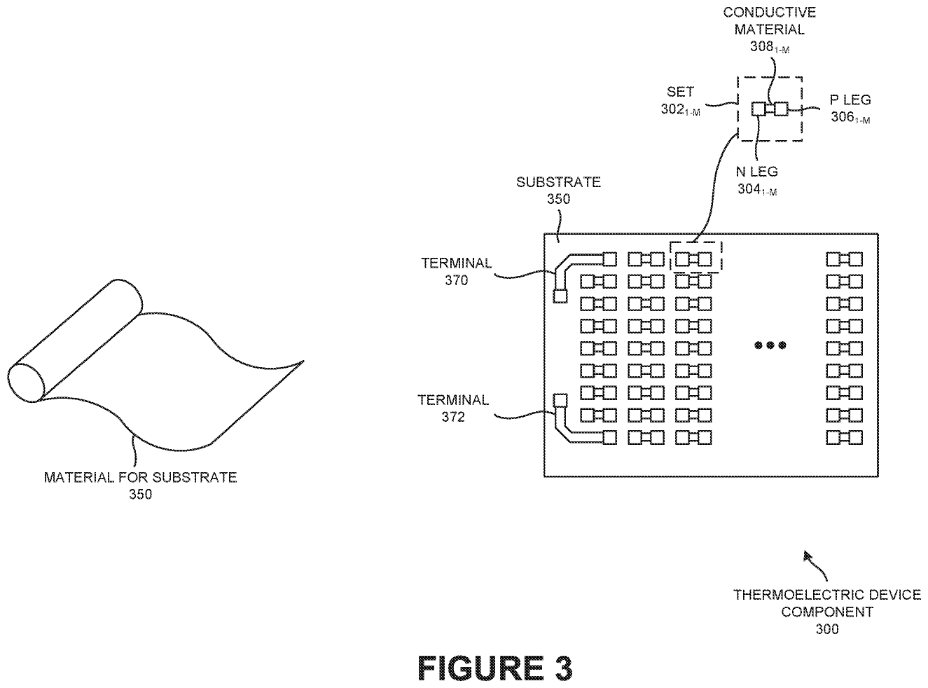

FIG. 3 shows a top view of a thermoelectric device component 300, according to one or more embodiments. Here, in one or more embodiments, a number of sets of N and P legs (e.g., sets 302_{1-M} including N legs 304_{1-M} and P legs 306_{1-M} therein) may be deposited on a substrate 350 (e.g., plastic, metal clad laminate) using a roll-to-roll process discussed above. FIG. 3 also shows a conductive material 308_{1-M} contacting both a set 302_{1-M} and substrate 350, according to one or more embodiments; an N leg 304_{1-M} and a P leg 306_{1-M} form a set 302_{1-M}, in which N leg 304_{1-M} and P leg 306_{1-M} electrically contact each other through conductive material 308_{1-M}. Terminals 370 and 372 may be electrically conductive leads to measure the potential difference generated by a thermoelectric device including thermoelectric device component 300.

Exemplary thermoelectric devices discussed herein may find utility in solar and solar thermal applications. As discussed above, traditional thermoelectric devices may have a size limitation and may not scale to a larger area. For example, a typical solar panel may have an area in the square meter (m²) range and the traditional thermoelectric device may have an area in the square inch range. A thermoelectric device in accordance with the exemplary embodiments may be of varying sizes and/or dimensions ranging from a few mm² to a few m².

Additionally, exemplary thermoelectric devices may find use in low temperature applications such as harvesting body heat in a wearable device, automotive devices/components and Internet of Things (IoT). Entities (e.g., companies, start-ups, individuals, conglomerates) may possess expertise to design and/or develop devices that require thermoelectric modules, but may not possess expertise in the fabrication and packaging of said thermoelectric modules. Alternately, even though the entities may possess the requisite expertise in the fabrication and packaging of the thermoelectric modules, the entities may not possess a comparative advantage with respect to the aforementioned processes.

In one scenario, an entity may create or possess a design pattern for a thermoelectric device. Said design pattern may be communicated to another entity associated with a thermoelectric platform to be tangibly realized as a thermoelectric device. It could also be envisioned that the another entity may provide training with regard to the fabrication processes to the one entity or outsource aspects of the fabrication processes to a third-party. Further, the entire set of processes involving Intellectual Property (IP) generation and manufacturing/fabrication of the thermoelectric device may be handled by a single entity. Last but not the least, the entity may generate the IP involving manufacturing/fabrication of the thermoelectric device and outsource the actual manufacturing/fabrication processes to the another entity.

All possible combinations of entities and third-parties are within the scope of the exemplary embodiments discussed herein.

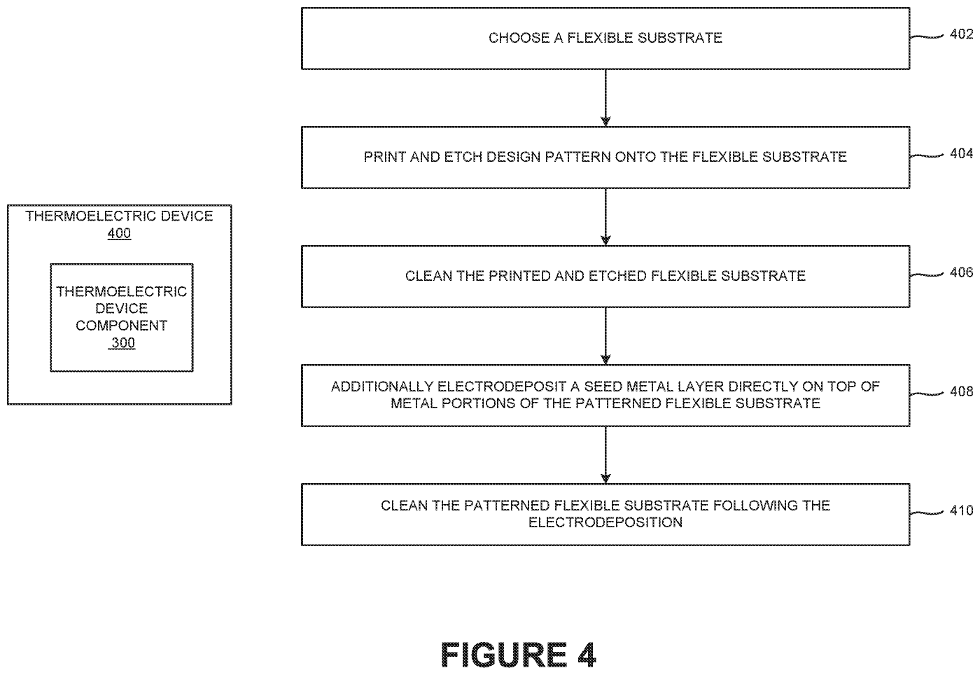

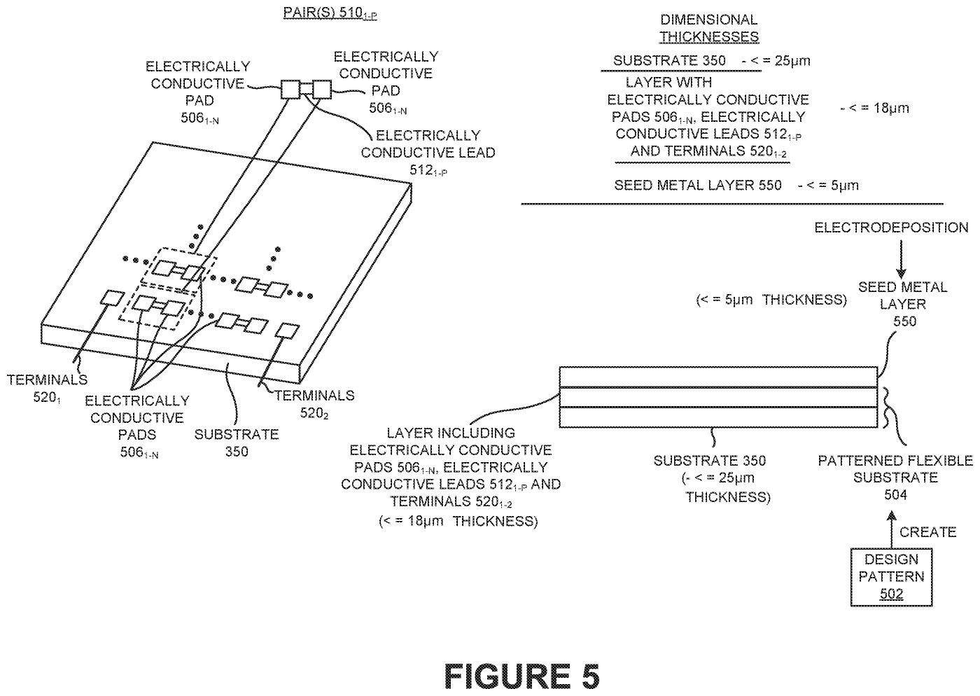

FIG. 4 shows the operations involved in realizing a patterned flexible substrate (e.g., patterned flexible substrate 504 shown in FIG. 5) of a thermoelectric device 400 as per a design pattern (e.g., design pattern 502 shown in FIG. 5), according to one or more embodiments. In one or more embodiments, operation 402 may involve choosing a flexible substrate (e.g., substrate 350) onto which, in operation 404, design pattern 502 may be printed (e.g., through inkjet printing, direct write, screen printing) and etched onto the flexible substrate. In one or more embodiments, a dimensional thickness of substrate 350 may be less than or equal to 25 μm.

Etching, as defined above, may refer to the process of removing (e.g., chemically) unwanted metal (say, Cu) from the patterned flexible substrate. In one example embodiment, a mask (e.g., a shadow mask) or a resist may be placed on portions of the patterned flexible substrate corresponding to portions of the metal that are to remain after the etch. Here, in one or more embodiments, the portions of the metal that remain on the patterned flexible substrate may be electrically conductive pads, electrically conductive leads and terminals formed on a surface of the patterned flexible substrate. FIG. 5 shows a patterned flexible substrate 504 including a number of electrically conductive pads 506_{1-N} formed thereon. Each electrically conductive pad 506_{1-N} may be a flat area of the metal that enables an electrical connection.

Also, FIG. 5 shows a majority set of the electrically conductive pads 506_{1-N} as including pairs 510_{1-P} of electrically conductive pads 506_{1-N} in which one electrically conductive pad 506_{1-N} may be electrically paired to another electrically conductive pad 506_{1-N} through an electrically conductive lead 512_{1-P} also formed on patterned flexible substrate 504; terminals 520₁₋₂ (e.g., analogous to terminals 370 and 372) may also be electrically conductive leads to measure the potential difference generated by the thermoelectric device/module fabricated based on design pattern 502. The aforementioned potential difference may be generated based on heat (or, cold) applied at an end of the thermoelectric device/module.

It should be noted that the configurations of the electrically conductive pads 506_{1-N}, electrically conductive leads 512_{1-P} and terminals 520₁₋₂ shown in FIG. 5 are merely for example purposes, and that other example configurations are within the scope of the exemplary embodiments discussed herein. It should also be noted that patterned flexible substrate 504 may be formed based on design pattern 502 in accordance with the printing and etching discussed above.

Example etching solutions employed may include but are not limited to ferric chloride and ammonium persulphate. Referring back to FIG. 4, operation 406 may involve cleaning the printed and etched flexible substrate. For example, acetone, hydrogen peroxide or alcohol may be employed therefor. Other forms of cleaning are within the scope of the exemplary embodiments discussed herein. In one or more embodiments, the aforementioned processes discussed in FIG. 4 may result in a dimensional thickness of electrically conductive pads 506_{1-N}, electrically conductive leads 512_{1-P} and terminals 520₁₋₂ being less than or equal to 18 μm.

The metal (e.g., Cu) finishes on the surface of patterned flexible substrate 504 may oxidize over time if left unprotected. As a result, in one or embodiments, operation 408 may involve additionally electrodepositing a seed metal layer 550 including Chromium (Cr), Nickel (Ni) and/or Gold (Au) directly on top of the metal portions (e.g., electrically conductive pads 506_{1-N}, electrically conductive leads 512_{1-P}, terminals 520₁₋₂) of patterned flexible substrate 504 following the printing, etching and cleaning. In one or more embodiments, a dimensional thickness of seed metal layer 550 may be less than or equal to 5 μm.

In one example embodiment, surface finishing may be employed to electrodeposit seed metal layer 550; the aforementioned surface finishing may involve Electroless Nickel Immersion Gold (ENIG) finishing. Here, a coating of two layers of metal may be provided over the metal (e.g., Cu) portions of patterned flexible substrate 504 by way of Au being plated over Ni. Ni may be the barrier layer between Cu and Au. Au may protect Ni from oxidization and may provide for low contact resistance. Other forms of surface finishing/electrodeposition may be within the scope of the exemplary embodiments discussed herein. It should be noted that seed metal layer 550 may facilitate contact of sputter deposited N-type thermoelectric legs (to be discussed below) and P-type thermoelectric legs (to be discussed below) thereto.

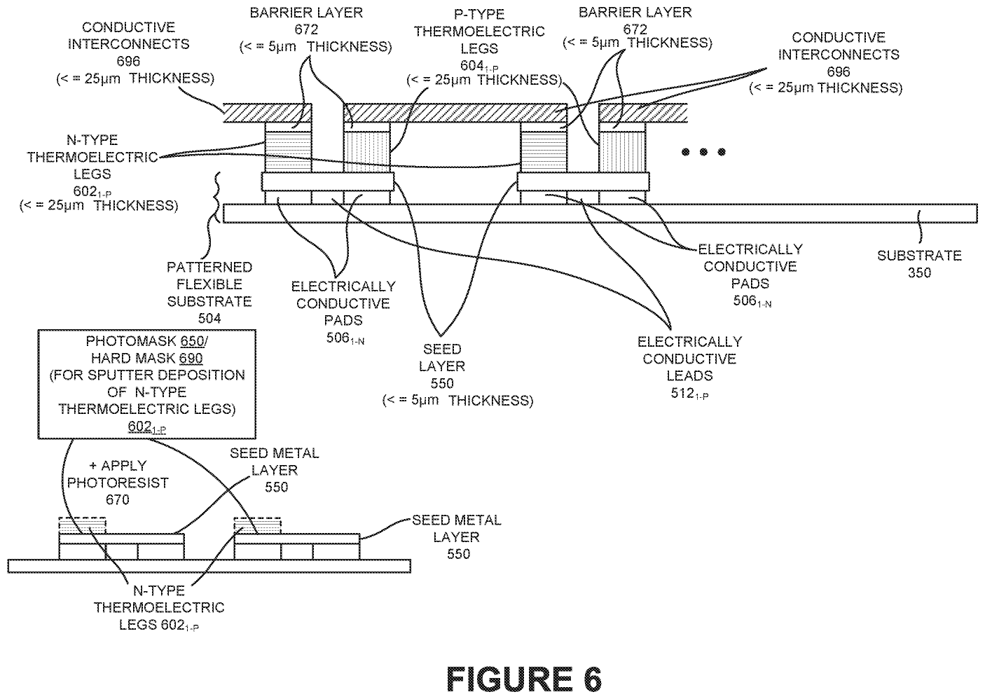

In one or more embodiments, operation 410 may then involve cleaning patterned flexible substrate 504 following the electrodeposition. FIG. 6 shows an N-type thermoelectric leg 602_{1-P} and a P-type thermoelectric leg 604_{1-P} formed on each pair 510_{1-P} of electrically conductive pads 506_{1-N}, according to one or more embodiments. In one or more embodiments, the aforementioned N-type thermoelectric legs 602_{1-P} and P-type thermoelectric legs 604_{1-P} may be formed on the surface finished patterned flexible substrate 504 (note: in FIG. 6, seed layer 550 is shown as surface finishing over electrically conductive pads 506_{1-N}/leads 512_{1-P}; terminals 520₁₋₂ have been omitted for the sake of clarity) of FIG. 5 through sputter deposition.

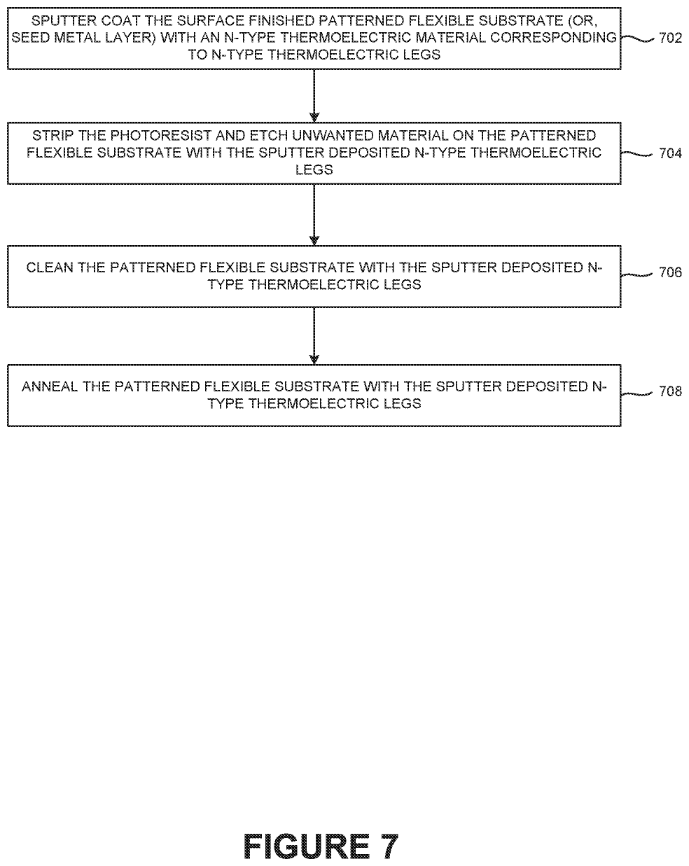

FIG. 7 details the operations involved in sputter deposition of N-type thermoelectric legs 602_{1-P} on the surface finished patterned flexible substrate 504 (or, seed metal layer 550) of FIG. 5, according to one or more embodiments. In one or more embodiments, the aforementioned process may involve a photomask 650 (shown in FIG. 6) on which patterns corresponding/complementary to the N-type thermoelectric legs 602_{1-P} may be generated. In one or more embodiments, a photoresist 670 (shown in FIG. 6) may be applied on the surface finished patterned flexible substrate 504, and photomask 650 placed thereon. In one or more embodiments, operation 702 may involve sputter coating (e.g., through magnetron sputtering) of the surface finished patterned flexible substrate 504 (or, seed metal layer 550) with an N-type thermoelectric material corresponding to N-type thermoelectric legs 602_{1-P}, aided by the use of photomask 650. The photoresist 670/photomask 650 functions are well understood to one skilled in the art; detailed discussion associated therewith has been skipped for the sake of convenience and brevity.

In one or more embodiments, operation 704 may involve stripping (e.g., using solvents such as dimethyl sulfoxide or alkaline solutions) of photoresist 670 and etching of unwanted material on patterned flexible substrate 504 with sputter deposited N-type thermoelectric legs 602_{1-P}. In one or more embodiments, operation 706 may involve cleaning the patterned flexible substrate 504 with the sputter deposited N-type thermoelectric legs 602_{1-P}; the cleaning process may be similar to the discussion with regard to FIG. 4.

In one or more embodiments, operation 708 may then involve annealing the patterned flexible substrate 504 with the sputter deposited N-type thermoelectric legs 602_{1-P}; the annealing process may be conducted (e.g., in air or vacuum) at 175° C. for 4 hours. In one or more embodiments, the annealing process may remove internal stresses and may contribute stability of the sputter deposited N-type thermoelectric legs 602_{1-P}. In one or more embodiments, a dimensional thickness of the sputter deposited N-type thermoelectric legs 602_{1-P} may be less than or equal to 25 μm.

It should be noted that P-type thermoelectric legs 604_{1-P} may also be sputter deposited on the surface finished pattern flexible substrate 504. The operations associated therewith are analogous to those related to the sputter deposition of N-type thermoelectric legs 602_{1-P}. Obviously, photomask 650 may have patterns corresponding/complementary to the P-type thermoelectric legs 604_{1-P} generated thereon. Detailed discussion associated with the sputter deposition of P-type thermoelectric legs 604_{1-P} has been skipped for the sake of convenience; it should be noted that a dimensional thickness of the sputter deposited P-type thermoelectric legs 604_{1-P} may also be less than or equal to 25 μm.

It should be noted that the sputter deposition of P-type thermoelectric legs 604_{1-P} on the surface finished patterned flexible substrate 504 may be performed after the sputter deposition of N-type thermoelectric legs 602_{1-P} thereon or vice versa. Also, it should be noted that various feasible forms of sputter deposition are within the scope of the exemplary embodiments discussed herein. In one or more embodiments, the sputter deposited P-type thermoelectric legs 604_{1-P} and/or N-type thermoelectric legs 602_{1-P} may include a material chosen from one of: Bismuth Telluride (Bi₂Te₃), Bismuth Selenide (Bi₂Se₃), Antimony Telluride (Sb₂Te₃), Lead Telluride (PbTe), Silicides, Skutterudites and Oxides.

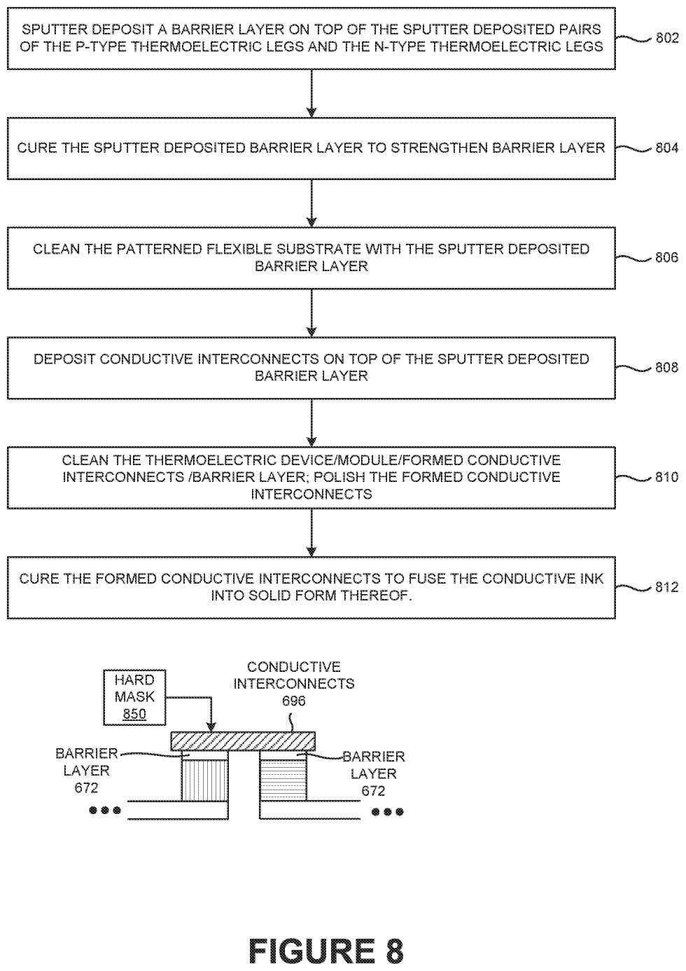

FIG. 8 details operations involved in deposition of a barrier layer 672 (refer to FIG. 6) on top of the sputter deposited pairs of P-type thermoelectric legs 604_{1-P} and N-type thermoelectric legs 602_{1-P} and forming conductive interconnects 696 on top of barrier layer 672, according to one or more embodiments.

In one or more embodiments, operation 802 may involve sputter depositing barrier layer 672 (e.g., film) on top of the sputter deposited pairs of the P-type thermoelectric legs 604_{1-P} and the N-type thermoelectric leg 602_{1-P} discussed above. In one or more embodiments, barrier layer 672 may be electrically conductive and may have a higher melting temperature than the thermoelectric material forming the P-type thermoelectric legs 604_{1-P} and the N-type thermoelectric legs 602_{1-P}. In one or more embodiments, barrier layer 672 may prevent corruption (e.g., through diffusion, sublimation) of one layer (e.g., the thermoelectric layer including the P-type thermoelectric legs 604_{1-P} and the N-type thermoelectric legs 602_{1-P}) by another layer. An example material employed as barrier layer 672 may include but is not limited to Cr, Ni or Au. Further, in one or more embodiments, barrier layer 672 may further aid metallization contact therewith (e.g., with conductive interconnects 696).

In one or more embodiments, a dimensional thickness of barrier layer 672 may be less than or equal to 5 μm. It is obvious that another photomask (not shown) analogous to photomask 650 may be employed to aid the patterned sputter deposition of barrier layer 672; details thereof have been skipped for the sake of convenience and clarity. In one or more embodiments, operation 804 may involve may involve curing barrier layer 672 at 175° C. for 4 hours to strengthen barrier layer 672. In one or more embodiments, operation 806 may then involve cleaning patterned flexible substrate 504 with barrier layer 672.

In one or more embodiments, operation 808 may involve depositing conductive interconnects 696 on top of barrier layer 672. In one example embodiment, the aforementioned deposition may be accomplished by screen printing silver (Ag) ink or other conductive forms of ink on barrier layer 672. Other forms of conductive interconnects 696 based on conductive paste(s) are within the scope of the exemplary embodiments discussed herein. As shown in FIG. 8, a hard mask 850 may be employed to assist the selective application of conductive interconnects 696 based on screen printing of Ag ink. In one example embodiment, hard mask 850 may be a stencil.

In one or more embodiments, the screen printing of Ag ink may contribute to the continued flexibility of the thermoelectric device/module and low contact resistance. In one or more embodiments, operation 810 may involve cleaning (e.g., using one or more of the processes discussed above) the thermoelectric device/module/formed conductive interconnects 696/barrier layer 672 and polishing conductive interconnects 696. In one example embodiment, the polishing may be followed by another cleaning process. In one or more embodiments, operation 812 may then involve curing conductive interconnects 696 at 175° C. for 4 hours to fuse the conductive ink into solid form thereof. In one or more embodiments, conductive interconnects 696 may have a dimensional thickness less than or equal to 25 m.

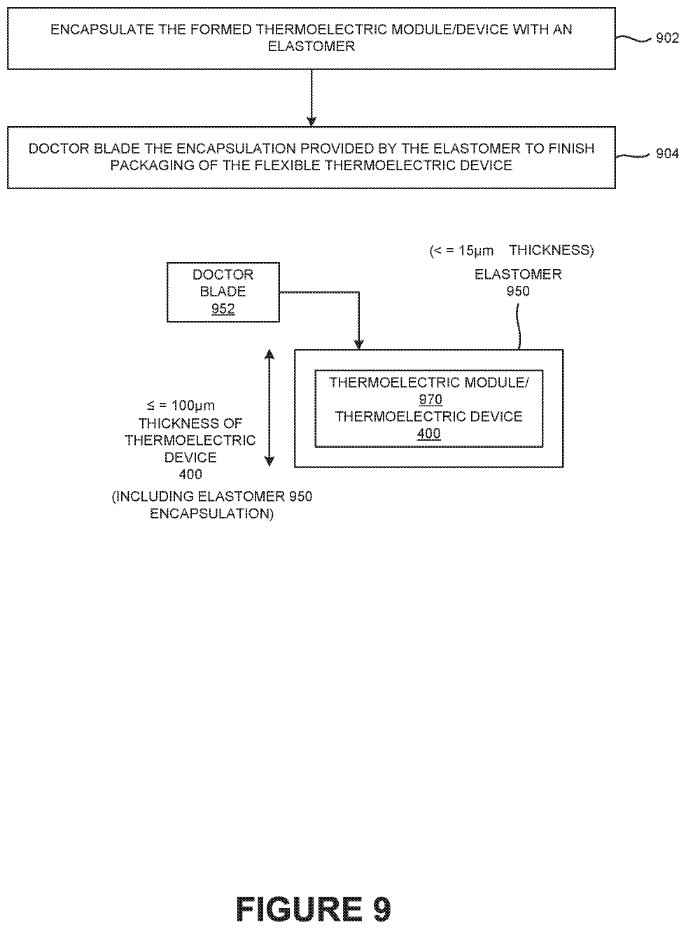

FIG. 9 details the operations involved in encapsulating the thermoelectric device (e.g., thermoelectric module 970)/module discussed above, according to one or more embodiments. In one or more embodiments, operation 902 may involve encapsulating the formed thermoelectric module (e.g., thermoelectric module 970)/device (with barrier layer 672 and conductive interconnects 696) with an elastomer 950 to render flexibility thereto. In one or more embodiments, as shown in FIG. 9, the encapsulation provided by elastomer 950 may have a dimensional thickness of less than or equal to 15 m. In one or more embodiments, operation 904 may involve doctor blading (e.g., using doctor blade 952) the encapsulation provided by elastomer 950 to finish packaging of the flexible thermoelectric device/module discussed above.

In one or more embodiments, the doctor blading may involve controlling precision of a thickness of the encapsulation provided by elastomer 950 through doctor blade 952. In one example embodiment, elastomer 950 may be silicone. Here, said silicone may be loaded with nano-size aluminum oxide (Al₂O₃) powder to enhance thermal conductivity thereof to aid heat transfer across the thermoelectric module.

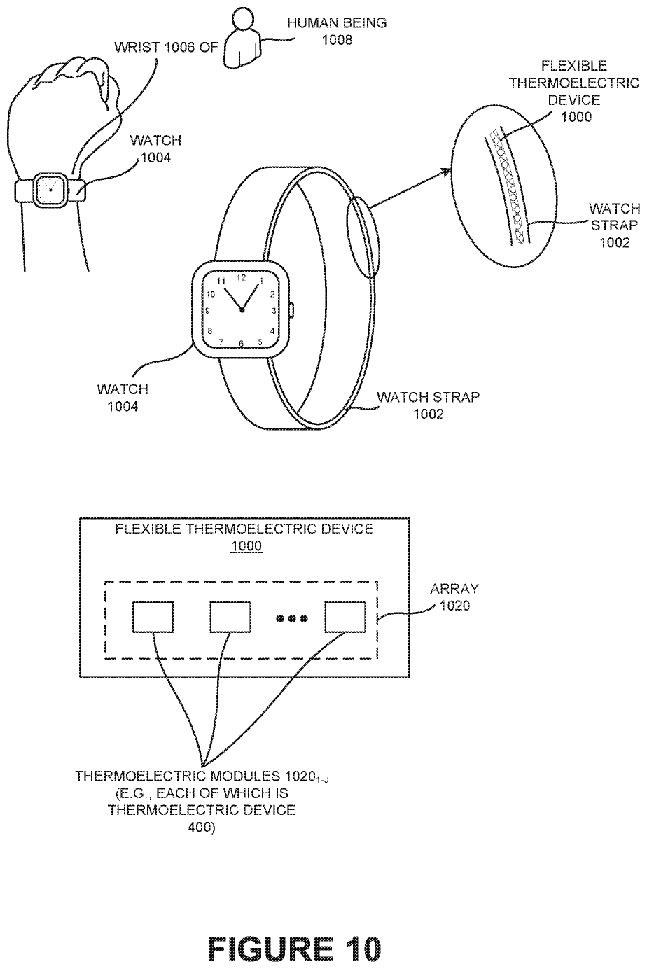

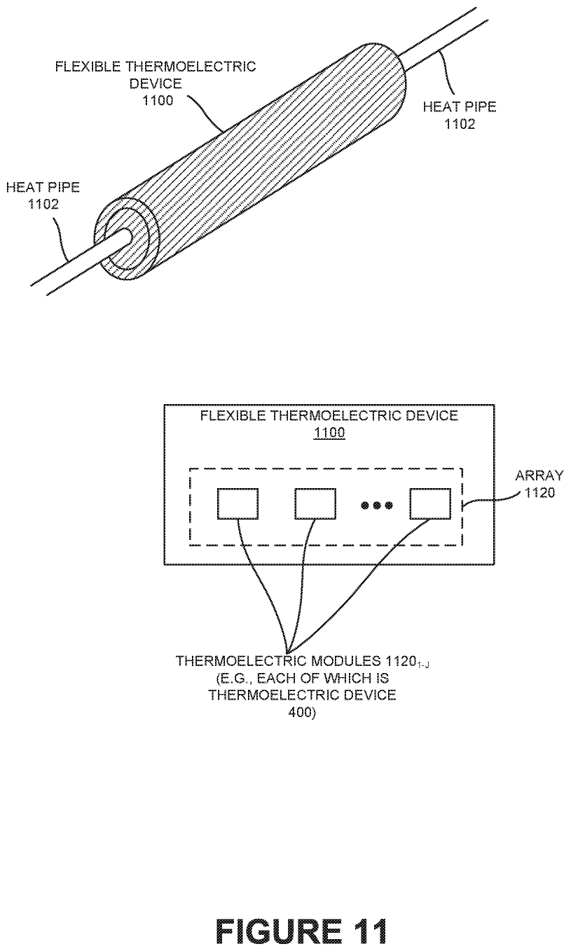

In one or more embodiments, as seen above, all operations involved in fabricating the thermoelectric device/module (e.g., thermoelectric device 400) render said thermoelectric device/module flexible. FIG. 10 shows a flexible thermoelectric device 1000 discussed herein embedded within a watch strap 1002 of a watch 1004 completely wrappable around a wrist 1006 of a human being 1008; flexible thermoelectric device 1000 may include an array 1020 of thermoelectric modules 1020_{1-J} (e.g., each of which is thermoelectric device 400) discussed herein. In one example embodiment, flexible thermoelectric device 1000 may serve to augment or substitute power derivation from a battery of watch 1004. FIG. 11 shows a flexible thermoelectric device 1100 discussed herein wrapped around a heat pipe 1102; again, flexible thermoelectric device 1100 may include an array 1120 of thermoelectric modules 1120_{1-J} (e.g., each of which is thermoelectric device 400) discussed herein. In one example embodiment, flexible thermoelectric device 1100 may be employed to derive thermoelectric power (e.g., through array 1120) from waste heat from heat pipe 1102.

It should be noted that although photomask 650 is discussed above with regard to deposition of N-type thermoelectric legs 602_{1-P} and a P-type thermoelectric legs 604_{1-P}, the aforementioned deposition may, in one or more other embodiments, involve a hard mask 690, as shown in FIG. 6. Further, it should be noted that flexible thermoelectric device 400/1000/1100 may be fabricated/manufactured such that the aforementioned device is completely wrappable and bendable around a system element (e.g., watch 1004, heat pipe 1102) that requires said flexible thermoelectric device 400/1000/1100 to perform a thermoelectric power generation function using the system element.

The abovementioned flexibility of thermoelectric device 400/1000/1100 may be enabled through proper selection of flexible substrates (e.g., substrate 350) and manufacturing techniques/processes that aid therein, as discussed above. Further, flexible thermoelectric device 1000/1100 may be bendable 360° such that the entire device may completely wrap around the system element discussed above. Still further, in one or more embodiments, an entire dimensional thickness of the flexible thermoelectric module (e.g., flexible thermoelectric device 400) in a packaged form may be less than or equal to 100 μm, as shown in FIG. 9.

Last but not the least, as the dimensions involved herein are restricted to less than or equal to 100 μm, the flexible thermoelectric device/module discussed above may be regarded as being thin-film based (e.g., including processes involved in fabrication thereof).

As seen above, thermoelectric modules/devices (e.g., thermoelectric module 970, embodiments of FIGS. 3-8) discussed above provide for flexibility related advantages that aid use thereof in several applications. Although FIG. 10 shows one such example application within watch strap 1002 of watch 1004, exemplary embodiments to be discussed below are related to another application of the aforementioned thermoelectric modules/devices with respect to watches. In one or more embodiments, these thermoelectric modules/devices may find use as a source of power to quartz watches; thus, the thermoelectric modules/devices may replace the need to power quartz watches using batteries.

The disadvantages of battery powered watches may be manifold. The battery (e.g., a cell battery) of a quartz watch may frequently need to be replaced, leading to bad user experience of a wearer thereof, in addition to costs associated therewith. In the case of an inexpensive quartz watch, the cost of a replacement battery may constitute a significant portion of the original cost of the watch. Additionally, quartz watches may offer limited technical differentiation thereacross. Further, early career and middle-aged professionals may prefer smart watches that offer features related to tracking health parameters thereof including but not limited to heart rate, blood pressure and even sleep cycles. The aforementioned tracking may warrant constant wearing of smart watches.

In order to provide an efficient and compact solution to one or more of the abovementioned problems, exemplary embodiments provide for a means to harvest body heat to thermoelectrically power quartz based watches. Given the tiny power requirements of quartz watches, the thermoelectric modules/devices (e.g., thermoelectric module 970, embodiments of FIGS. 3-8) discussed above, when integrated with quartz watches, may possess the capability to provide perpetual battery-less experience to users thereof, according to one or more embodiments.

In a conventional thermoelectrically powered wrist watch, a larger amount of heat energy may be absorbed into a case thereof, deeming it necessary to prevent a rise of temperature inside the case; otherwise, the aforementioned rise in temperature inside the case may result in temperatures at both ends of a thermoelectric element embedded in the watch being in equilibrium with each other; in other words, a temperature difference between both ends of the thermoelectric element becomes zero, resulting in the thermoelectric element being brought to a state capable of generating no power.

Also, the Carnot cycle including adiabatic and isothermal operations provides the fundamental limit to the energy obtainable from a temperature difference. The Carnot efficiency (η) may be obtained as:

$$η = 1 - \frac{{T}_{cold}}{{T}_{hot}} ,$$

where T_{cold} and Tₕₒₜ are the temperatures (in degrees K) of the cold and hot regions across which the thermoelectric element discussed above operates. Accordingly, the Carnot efficiency may be limited for small temperature differences; for example, going from body temperature (37° C.) to that of a cool room (20° C.) yields a Carnot efficiency of only 5.5 percent.

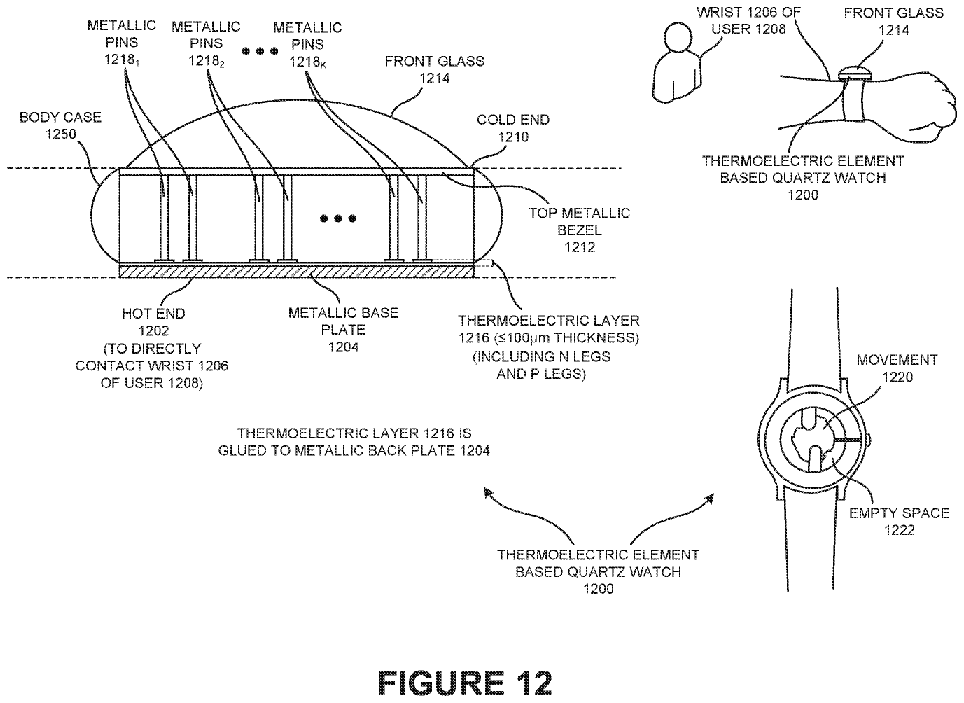

In one or more embodiments, thus, sustaining a differential temperature across the thermoelectric element discussed above may be essential to produce useful power. In one or more embodiments, the aforementioned may be done through channeling heat flow through one or more element(s) having sub-millimeter (sub-mm) thickness, e.g., a pogo pin. Pogo pins are commonly used in probe cards in the semiconductor industry for testing wafers, and are well known to one skilled in the art. Therefore, detailed discussed associated therewith has been skipped for the sake of convenience. FIG. 12 shows a front view of a thermoelectric element based quartz watch 1200, according to one or more embodiments. In one or more embodiments, in thermoelectric element based quartz watch 1200, a differential temperature may be sustained through channeling heat flow through a metallic pin (e.g., pogo pin) of sub-millimeter thickness.

As shown in FIG. 12, a hot end 1202 of thermoelectric element based quartz watch 1200 may be a metallic back plate 1204 thereof configured to directly contact a wrist 1206 of a user 1208, and a cold end 1210 of thermoelectric element based quartz watch 1200 may be a top metallic bezel 1212 (or, frame) thereof configured to be covered with glass (e.g., shown as front glass 1214 in FIG. 12). While a specific metallic back plate 1204 is shown as contacting wrist 1206, it should be noted that any thermally conductive (e.g., metallic, ceramic) element configured to directly contact wrist 1206 and configured to provide for a temperature difference between the body heat of user 1208 and a temperature associated with top metallic bezel 1212 may be interpreted as metallic back plate 1204.

In one or more embodiments, the direct contact between metallic back plate 1204 and wrist 1206 may occur by way of user 1208 wearing thermoelectric element based quartz watch 1200, as shown in FIG. 12. In one or more embodiments, hot end 1202 and cold end 1210 may be separated from one another by a thermoelectric layer 1216 (e.g., thermoelectric module 970, without elastomer 950; embodiments of FIGS. 3-8), without substantially changing a design of thermoelectric element based quartz watch 1200. FIG. 12 shows an empty space 1222 around a movement 1220 (e.g., mechanism) of thermoelectric element based quartz watch 1200 configured to enable incorporation of metallic pins discussed above.

In one or more embodiments, thermoelectric layer 1216 may be shaped in accordance with a shape of thermoelectric element based quartz watch 1200/metallic back plate 1204; in other words, the shape of thermoelectric layer 1216 may correspond to a shape of thermoelectric element based quartz watch 1200/metallic back plate 1204. For example, in the case of a round shaped thermoelectric element based quartz watch 1200, a round shaped metallic back plate 1204 and/or a round shaped dial of thermoelectric element based quartz watch 1200, thermoelectric layer 1216 may be made into a round shaped thin film configured to be glued (e.g., using thermally conductive glue) to metallic back plate 1204 on an inside thereof (e.g., inside of metallic back plate 1204, inside of thermoelectric element based quartz watch 1200) such that, when worn, an outside of metallic back plate 1204 contacts wrist 1206. It is obvious that dimensions of thermoelectric layer 1216 and structure thereof may be an analogous to the embodiments disclosed in FIGS. 3-8.

In a typical quartz watch, there may not be enough room for a state-of-the-art bulk thermoelectric device/element. Exemplary embodiments discussed herein may offer the unique advantage of incorporating a thermoelectric layer 1216 less than or equal to 100 μm in dimensional thickness in the quartz watch and, thereby, adding negligible weight thereto. The dimensionality of thermoelectric layer 1216 may make incorporation thereof into the quartz watch easy. Direct contact of an analogous thermoelectric layer 1216 with cold end 1210 may not be possible due to space limitations within the quartz watch and delicateness of thermoelectric layer 1216.

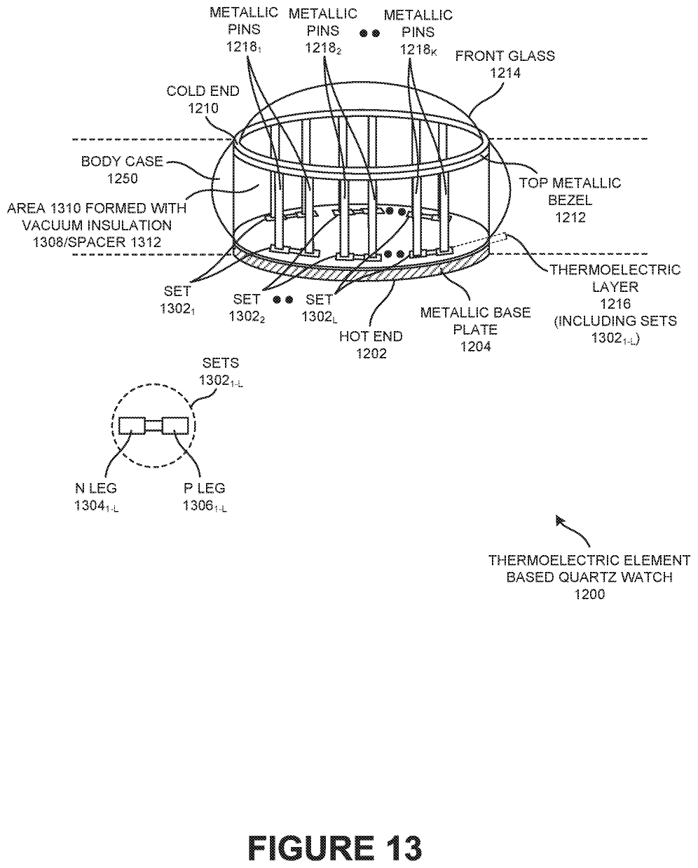

In one or more embodiments, in order to better maintain the temperature difference between hot end 1202 and cold end 1210 and to provide thermal contact therebetween, a set of metallic pins 1218_{1-K} directly contacting top metallic bezel 1212 may be configured to directly contact thermoelectric layer 1216. FIG. 13 shows a perspective view of thermoelectric element based quartz watch 1200, according to one or more embodiments. Here, in one or more embodiments, metallic pins 1218_{1-K} may directly protrude from top metallic bezel 1212 to directly contact thermoelectric layer 1216. FIG. 13 shows a circular shaped thermoelectric layer 1216 including sets 1302_{1-L} of N legs 1304_{1-L} and P legs 1306_{1-L} (analogous to sets 302_{1-M} including N legs 304_{1-M} and P legs 306_{1-M} of FIG. 3). In one or more embodiments, a metallic pin 1218_{1-K} may protrude from top metallic bezel 1212 to directly contact a thermoelectric leg (N leg 1304_{1-L}, P leg 1306_{1-L}) such that metallic pins 1218_{1-K} connect all thermoelectric legs (N legs 1304_{1-L}, P legs 1306_{1-L}) to top metallic bezel 1212.

FIG. 13 is merely an example embodiment. It should be noted that, in some embodiments, a number of sets 1302_{1-L} of N legs 1304_{1-L} and P legs 1306_{1-L} may be more than half the number of metallic pins 1218_{1-K}. In other words, there may be some sets 1302_{1-L} of N legs 1304_{1-L} and P legs 1306_{1-L} not being coupled to top metallic bezel 1212 by way of metallic pins 1218_{1-K}. All reasonable variations are within the scope of the exemplary embodiments discussed herein.

For an isothermal surface, a direction of heat flux may be normal to cross-sectional area thereof. For a given heat flux, the length of the thermoelectric legs may be directly proportional to a temperature difference thereacross. However, the longer the thermoelectric legs, the lower the electrical resistance and power. Exemplary embodiments solve the aforementioned problem through metallic pins 1218_{1-K} that enable utilization of temperature difference for thermoelectric effects even with short thermoelectric legs of thermoelectric layer 1216.

In one or more embodiments, heat may be conducted from wrist 1206 (e.g., skin temperature at 34° C.) to metallic back plate 1204, and from then to thermoelectric layer 1216, where each N leg 1304_{1-L} and P leg 1306_{1-L} may be in contact with separate metallic pins 1218_{1-K}. In one or more embodiments, the aforementioned separate metallic pins 1218_{1-K} may, in turn, directly connect to top metallic bezel 1212 (e.g., a metallic ring, a metallic frame); the aforementioned top metallic bezel 1212 may connect to a rest of a frame of thermoelectric element based quartz watch 1200 and a body case thereof. In some embodiments, as shown in FIG. 13, an area (e.g., area 1310) inside thermoelectric element based quartz watch 1200 between top metallic bezel 1212 and thermoelectric layer 1216, and around metallic pins 1218_{1-K}, may be at least partially vacuum insulated (e.g., shown as vacuum insulation 1308; example would be Thermos®-plastic) such that heat is blocked therein. In one or more embodiments, temperatures of hot end 1202 and cold end 1210 may be maintained through narrow heat flow paths restricted via metallic pins 1218_{1-K}.

In one or more embodiments, metallic pins 1218_{1-K} may be pogo pins. In one or more embodiments, metallic pins 1218_{1-K} may be of copper (Cu) and Gold (Au) (e.g., Au coated Cu). In one or more embodiments, while top metallic bezel 1212 may typically be a metal ring, ceramic rings/elements are within the scope of the exemplary embodiments discussed herein. In certain inexpensive watches, even plastic elements/rings and/or glass elements may substitute top metallic bezel 1212. To generalize, metallic pins 1218_{1-K} may protrude from a thermally conductive watch element (e.g., top metallic bezel 1212, metal ring, ceramic ring/element, plastic ring/element, glass, metal frame; elements substituting for top metallic bezel 1212 need not be bezels) attached to a body case (e.g., body case 1250 of thermoelectric element based quartz watch 1200; while body case 1250 may typically be metallic, body case 1250 may also be ceramic or plastic) of thermoelectric element based quartz watch 1200; similarly, metallic black plate 1204 may be another ceramic or a metallic thermally conductive watch element. In one or more embodiments, a few (e.g., 5-10) metallic pins 1218_{1-K} may suffice for the purpose of maintaining narrow heat flow paths discussed above. A large number of metallic pins 1218_{1-K} may increase contact resistance. Additionally, in one or more embodiments, each metallic pin 1218_{1-K} may be of sub-millimeter thickness.

It should be noted that top metallic bezel 1212 discussed above may be manufactured with metallic pins 1218_{1-K} protruding therefrom (e.g., based on appropriate holes drilled into top metallic bezel 1212 and metallic pins 1218_{1-K} coupled through said holes) configured to directly contact thermoelectric layer 1216. Thus, in one or more embodiments, powering elements of thermoelectric element based quartz watch 1200 may separately be manufactured scalably and efficiently. In one or more embodiments, thermoelectric element based quartz watch 1200 may thus be thermoelectrically powered perpetually without the requirement of a commercial battery. In one or more embodiments, the scalable manufacturability of thermoelectric elements may provide for easy replacement of the powering elements discussed above in thermoelectric element based quartz watch 1200. It should be noted that concepts associated with thermoelectric element based quartz watch 1200 may also be extended to pocket watches, where body heat on a chest portion (example body part, analogous to wrist 1206) of a user is harvested. Additionally, concepts discussed herein may apply to generic watches too; in some scenarios, the powering elements discussed herein may be utilized in conjunction with other powering elements (e.g., batteries).

In one or more embodiments, in the case of inexpensive watches, area 1310 discussed above may be at least partially filled with a spacer material (e.g., spacer 1312; example materials for spacer 1312 may include but are not limited to plastic and rubber; spacer 1312 may also be in the form of rings). FIG. 13 merely indicates area 1310 filled with transparent vacuum insulation 1308/spacer 1312 for the sake of clarity. It should be noted that vacuum insulation 1308/spacer 1312 can take a number of forms and shapes (e.g., rings) and may cover area 1310 partially or completely. Further, in some scenarios, empty space 1222 and area 1310 discussed above may be quite small or practically non-existent. In this case, in one or more embodiments, metallic pins 1218_{1-K} may protrude from an appropriate thermally conductive element (e.g., top metallic bezel 1212, plastic/ceramic/glass elements attached to body case 1250), go through a nesting element (e.g., a ring) around a dial movement of the watch (e.g., thermoelectric element based quartz watch 1200) and contact thermoelectric layer 1216.

Also, it should be noted that all design configurations of watches arising out of concepts associated with the exemplary embodiments discussed herein are enabled therethrough. Further, all configurations of metallic pins 1218_{1-K} protruding between top metallic bezel 1212 or substitutes thereof and thermoelectric layer 1216 and configurations of thermoelectric legs of thermoelectric layer 1216 are within the scope of the exemplary embodiments discussed herein. Thus, all reasonable variations are within the scope of the exemplary embodiments discussed herein.

Although the present embodiments have been described with reference to specific example embodiments, it will be evident that various modifications and changes may be made to these embodiments without departing from the broader spirit and scope of the various embodiments. Accordingly, the specification and drawings are to be regarded in an illustrative rather than a restrictive sense.

What is claimed is:

1. A thermoelectric element based watch comprising:
a first thermally conductive element configured to serve as a hot end of the thermoelectric element based watch, the hot end configured to directly contact a body part of a user wearing the thermoelectric element based watch;
a thin-film thermoelectric layer comprising a plurality of sets of thermoelectric legs formed on a substrate, each set of the plurality of sets comprising an N-type thermoelectric leg and a P-type thermoelectric leg electrically in contact with one another, a dimensional thickness of the thin-film thermoelectric layer being less than or equal to 100 μm, and the substrate of the thin-film thermoelectric layer directly contacting the first thermally conductive element on an inside of the thermoelectric element based watch as compared to an outside of the first thermally conductive element configured to serve as the hot end;
a second thermally conductive element attached to a body case of the thermoelectric element based watch, the second thermally conductive element configured to serve as a cold end of the thermoelectric element based watch; and
a plurality of metallic pins directly contacting both the second thermally conductive element on another inside of the thermoelectric element based watch as compared to another outside of the second thermally conductive element configured to serve as the cold end and at least one set of the plurality of sets of the thermoelectric legs of the thin-film thermoelectric layer,
wherein, based on the direct contact of the plurality of metallic pins with both the second thermally conductive element and the at least one set of the plurality of sets of the thermoelectric legs of the thin-film thermoelectric layer, the thermoelectric element based watch is configured to be powered in accordance with a temperature difference between the hot end and the cold end thereof.

2. The thermoelectric element based watch of claim 1, wherein the plurality of metallic pins comprises pogo pins.

3. The thermoelectric element based watch of claim 1, wherein each metallic pin of the plurality of metallic pins is of sub-millimeter thickness.

4. The thermoelectric element based watch of claim 1, wherein each metallic pin of the plurality of metallic pins is made of gold (Au) coated Copper (Cu).

5. The thermoelectric element based watch of claim 1, wherein the second thermally conductive element configured to serve as the cold end is one of: a metallic element, a plastic element, a glass element and a ceramic element.

6. The thermoelectric element based watch of claim 1, wherein the first thermally conductive element configured to serve as the hot end is a metallic back plate.

7. The thermoelectric element based watch of claim 1, wherein an empty space around a movement of the thermoelectric element based watch is configured to enable accommodation of the plurality of metallic pins therewithin.

8. The thermoelectric element based watch of claim 1, wherein the thin-film thermoelectric layer has a shape corresponding to a shape of the first thermally conductive element.

9. The thermoelectric element based watch of claim 1, wherein an area between the second thermally conductive element and the thin-film thermoelectric layer, and around the plurality of metallic pins, is one of: vacuum insulated and filled with a spacer material.

10. A thermoelectric component of a watch comprising:
a thin-film thermoelectric layer comprising a plurality of sets of thermoelectric legs formed on a substrate, each set of the plurality of sets comprising an N-type thermoelectric leg and a P-type thermoelectric leg electrically in contact with one another, a dimensional thickness of the thin-film thermoelectric layer being less than or equal to 100 μm, the substrate of the thin-film thermoelectric layer configured to directly contact a first thermally conductive element of the watch on an inside thereof as compared to an outside of the first thermally conductive element configured to serve as a hot end of the watch, and the hot end configured to directly contact a body part of a user wearing the watch; and
a plurality of metallic pins directly contacting at least one set of the plurality of sets of the thermoelectric legs of the thin-film thermoelectric layer and configured to also directly contact a second thermally conductive element of the watch on another inside thereof as compared to another outside of the second thermally conductive element configured to serve as a cold end of the watch,
wherein, based on the direct contact of the plurality of metallic pins with both the second thermally conductive element and the at least one set of the plurality of sets of the thermoelectric legs of the thin-film thermoelectric layer, the watch is configured to be powered in accordance with a temperature difference between the hot end and the cold end thereof.

11. The thermoelectric component of the watch of claim 10, wherein the plurality of metallic pins comprises pogo pins.

12. The thermoelectric component of the watch of claim 10, wherein each metallic pin of the plurality of metallic pins is of sub-millimeter thickness.

13. The thermoelectric component of the watch of claim 10, wherein each metallic pin of the plurality of metallic pins is made of Au coated Cu.

14. The thermoelectric component of the watch of claim 10, wherein the thin-film thermoelectric layer has a shape corresponding to a shape of the first thermally conductive element of the watch.

15. A thermoelectric element based watch comprising:
a first thermally conductive element configured to serve as a hot end of the thermoelectric element based watch, the hot end configured to directly contact a body part of a user wearing the thermoelectric element based watch;
a thin-film thermoelectric layer comprising a plurality of sets of thermoelectric legs formed on a substrate, each set of the plurality of sets comprising an N-type thermoelectric leg and a P-type thermoelectric leg electrically in contact with one another, a dimensional thickness of the thin-film thermoelectric layer being less than or equal to 100 μm, and the substrate of the thin-film thermoelectric layer directly contacting the first thermally conductive element on an inside of the thermoelectric element based watch as compared to an outside of the first thermally conductive element configured to serve as the hot end;
a second thermally conductive element attached to a body case of the thermoelectric element based watch, the second thermally conductive element configured to serve as a cold end of the thermoelectric element based watch; and
a plurality of metallic pins directly contacting both the second thermally conductive element on another inside of the thermoelectric element based watch as compared to another outside of the second thermally conductive element configured to serve as the cold end and at least one set of the plurality of sets of the thermoelectric legs of the thin-film thermoelectric layer,
wherein, based on the direct contact of the plurality of metallic pins with both the second thermally conductive element and the at least one set of the plurality of sets of the thermoelectric legs of the thin-film thermoelectric layer, the thermoelectric element based watch is configured to be powered in accordance with a temperature difference between the hot end and the cold end thereof, and
wherein an area between the second thermally conductive element and the thin-film thermoelectric layer, and around the plurality of metallic pins, is one of: vacuum insulated and filled with a spacer material.

16. The thermoelectric element based watch of claim 15, wherein at least one of:
the plurality of metallic pins comprises pogo pins,
each metallic pin of the plurality of metallic pins is of sub-millimeter thickness, and the each metallic pin of the plurality of metallic pins is made of Au coated Cu.

17. The thermoelectric element based watch of claim 15, wherein the second thermally conductive element configured to serve as the cold end is one of: a metallic element, a plastic element, a glass element and a ceramic element.

18. The thermoelectric element based watch of claim 15, wherein the first thermally conductive element configured to serve as the hot end is a metallic back plate.

19. The thermoelectric element based watch of claim 15, wherein an empty space around a movement of the thermoelectric element based watch is configured to enable accommodation of the plurality of metallic pins therewithin.

20. The thermoelectric element based watch of claim 15, wherein the thin-film thermoelectric layer has a shape corresponding to a shape of the first thermally conductive element.
